(19) United States
(12) Patent Application Publication
(10) Pub. No.: US 2014/0152349 A1
(43) Pub. Date: Jun. 5, 2014

(54) SEMICONDUCTOR DEVICE, MANUFACTURING METHOD THEREOF AND OPERATING METHOD THEREOF

(71) Applicant: MACRONIX INTERNATIONAL CO., LTD., Hsinchu (TW)

(72) Inventors: Chih-Ling Hung, Kaohsiung City (TW); Hsin-Liang Chen, Taipei City (TW); Wing-Chor Chan, Hsinchu City (TW)

(73) Assignee: MACRONIX INTERNATIONAL CO., LTD., Hsinchu (TW)

(21) Appl. No.: 13/690,597

(22) Filed: Nov. 30, 2012

(51) Int. Cl. H01L 23/60; H03K 17/06; H01L 21/20

(52) U.S. Cl. CPC H01L 23/60; H01L 21/20; H03K 17/063
USPC 327/109; 257/487; 438/478

(57) ABSTRACT

A semiconductor device, a manufacturing method thereof and an operating method thereof are provided. The semiconductor device includes a substrate, a first well, a second well, a first heavily doping region, a second heavily doping region, a third heavily doping region, and an electrode layer. The first and the second wells are disposed on the substrate. The first and the third heavily doping regions, which are separated from each other, are disposed in the first well, and the second heavily doping region is disposed in the second well. The electrode layer is disposed on the first well. Each of the second well, the first heavily doping region, and the second heavily doping region has a first type doping. Each of the substrate, the first well, and the third heavily doping region has a second type doping, which is complementary to the first type doping.

### BACKGROUND

1. Technical Field

The disclosure relates in general to a semiconductor device, a manufacturing method thereof, and an operating method thereof.

2. Description of the Related Art

With the development of semiconductor technology, varied semiconductor devices are invented. For example, memories, transistors and diodes are widely used in electric devices. However, a number of problems still require further improvements. For example, high voltage devices usually have a low holding voltage, latch-up effects may occur easily during normal operation, and the high voltage device may be triggered by unwanted power-on peak voltage.

In the development of semiconductor technology, researchers keep trying to improve those semiconductor devices, such as reducing the volume, increasing/reducing the turn on voltage, increasing/reducing the breakdown voltage, reducing the electric leakage, and solving the ESD issue.

### SUMMARY

The disclosure is directed to a method of a semiconductor device, a manufacturing method thereof, and an operating method thereof. With the design of an electrode layer in the semiconductor device, the current gain (Beta) is increased, the electrostatic discharge (ESD) protection is improved, and the occurrence of latch-up effects can be reduced.

According to an aspect of the present disclosure, a semiconductor device is provided. The semiconductor device comprises a substrate, a first well, a second well, a first heavily doping region, a second heavily doping region, a third heavily doping region, and an electrode layer. The first well and the second well are disposed on the substrate. The first heavily doping region and the third heavily doping region are disposed in the first well, and the second heavily doping region is disposed in the second well. The first heavily doping region and the third heavily doping region are separated from each other. The electrode layer is disposed on the first well. Each of the second well, the first heavily doping region, and the second heavily doping region has a first type doping. Each of the substrate, the first well, and the third heavily doping region has a second type doping. The first type doping is complementary to the second type doping.

According to another aspect of the present disclosure, a manufacturing method of a semiconductor device is provided. The manufacturing method comprises the following steps. A substrate is provided. A first well and a second well are formed on the substrate. A first heavily doping region is formed in the first well. A second heavily doping region is formed in the second well. A third heavily doping region is formed in the first well, wherein the first heavily doping region and the third heavily doping region are separated from each other. An electrode layer is formed on the first well, wherein each of the second well, the first heavily doping region, and the second heavily doping region has a first type doping, each of the substrate, the first well, and the third heavily doping region has a second type doping, and the first type doping is complementary to the second type doping.

According to further another aspect of the present disclosure, an operating method of a semiconductor device is provided. The semiconductor device comprises a substrate, a first well, a second well, a first heavily doping region, a second heavily doping region, a third heavily doping region, and an electrode layer; the first well and second well are disposed on the substrate;

the first heavily doping region is disposed in the first well; the second heavily doping region is disposed in the second well; the third well is disposed in the first well and is separated from the first well; the electrode layer is disposed on the first well; each of the second well, the first heavily doping region, and the second heavily doping region has a first type doping; each of the substrate, the first well, and the third heavily doping region has a second type doping; the first type doping is complementary to the second type doping. The operating method comprises the following steps. A gate voltage is applied to the electrode layer for generating an inversion layer between the first well and the electrode layer. An emitter voltage is applied to the first heavily doping region. A collector voltage is applied to the second heavily doping region. A base voltage is applied to the third heavily doping region.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a cross-section view of a semiconductor device of the first embodiment;

FIG. 2 shows a gate voltage-normalization Bate curve of a semiconductor device of an embodiment;

FIGS. 3A˜3D illustrate a manufacturing method of the semiconductor device of the first embodiment;

FIG. 4 shows a cross section view of a semiconductor device of the second embodiment;

FIG. 5 shows a cross section view of a semiconductor device of the third embodiment;

FIG. 6 shows a cross-section view of a semiconductor element of the fourth embodiment;

FIG. 7 shows a cross-section view of a semiconductor element of the fifth embodiment; and

FIGS. 8A˜8D illustrate a manufacturing method of the semiconductor device of the fifth embodiment.

### DETAILED DESCRIPTION

Several embodiments are disclosed below for elaborating the invention. The following embodiments are for the purpose of elaboration only, not for limiting the scope of protection of the invention. Besides, secondary elements are omitted in the following embodiments to highlight the technical features of the invention.

### First Embodiment

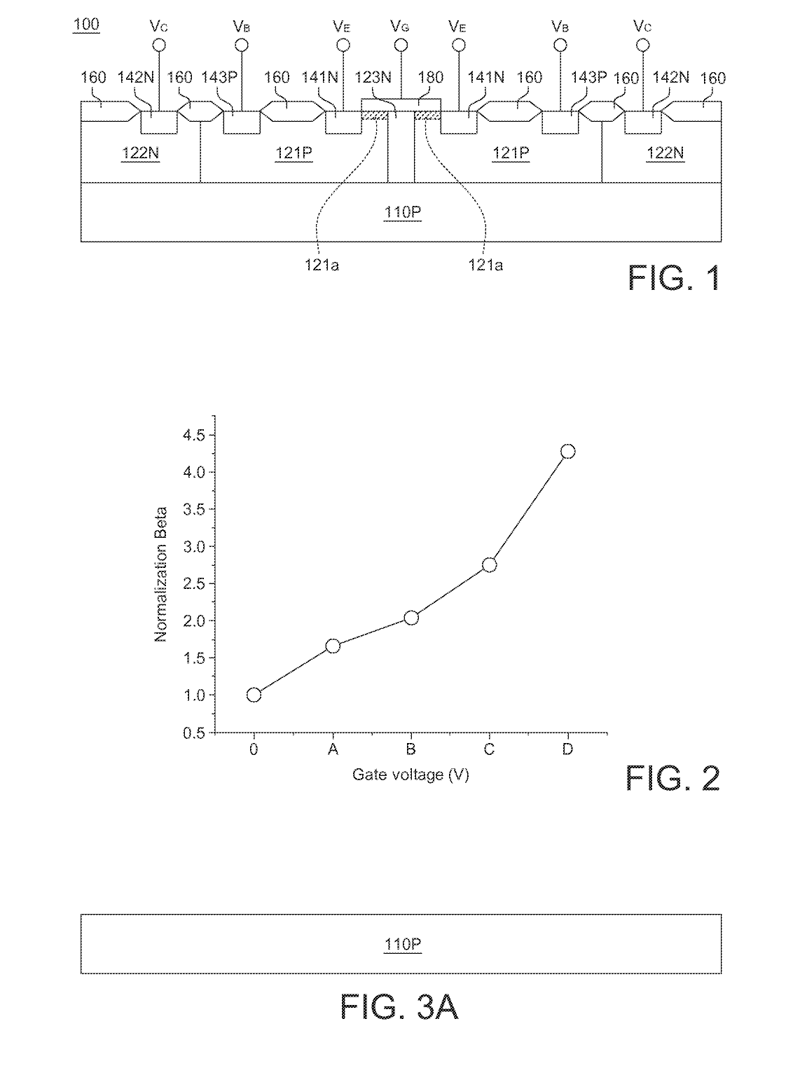

Referring to FIG. 1, a cross-section view of a semiconductor device 100 of the first embodiment is shown. The semiconductor device 100 includes at least a substrate 110P, a first well 121P, a second sell 122N, a first heavily doping region 141N, a second heavily doping region 142N, a third heavily doping region 143P, and an electrode layer 180.

The material of the substrate 110P can be P type silicon or N type silicon, for example. The first well 121P and the second well 122N are disposed on the substrate 110P. The first well 121P and the second well 122N may be a P type well or an N type well. The first well 121P and the second well 122N may also be a P type well/P+ buried layer stacked layer, a P+ implant layer, an N type well/N+ buried layer stacked layer, an N+ implant layer, or a deep N type well.

The first heavily doping region 141N and the third heavily doping region 143P are disposed in the first well 121P, the second heavily doping region 143N is disposed in the second well 122N, and the first and the third heavily doping regions are separated from each other. The doping concentrations of the first, second, and third heavily doping regions 141N, 142N, and 143P are larger than that of the first and second wells 121P and 122N, such that a good Ohmic contact is provided. The first, second, and third heavily doping regions 141N, 142N, and 143P may be P type heavily doping regions (P+) or N type heavily doping regions (N+).

The electrode layer 180 is disposed on the first well 121P. The material of the electrode layer 180 is polysilicon, for example.

Each of the second well 122N, the first heavily doping region 141N, and the second heavily doping region 142N has a first type doping, such as P type doping or N type doping. Each of the substrate 110P, the first well 121P, and the third heavily doping region 143P has a second type doping, such as N type doping or P type doping. The first type doping is complementary to the second type doping. In the present embodiment, the first type doping is the type doping, and the second type doping is P type doping.

As shown in FIG. 1, in the embodiment, the semiconductor device 100 can further include a field oxide (FOX) disposed on a junction between the first well 121P and the second well 122N. The material of the field oxide 160 is such as silicon dioxide (SiO₂). In addition, in the semiconductor device 100 of the present embodiment, an additional field oxide 160 can further be disposed between the third heavily doping region 143P and the first heavily doping region 141N to separate the two regions from each other.

In the embodiment, the semiconductor device 100 can further includes a third well 123N. As shown in FIG. 1, the third well 123N having the first type doing is disposed on the substrate 110P, and the first well 121P is disposed between the second well 122N and the third well 123N. In the embodiment, as shown in FIG. 1, the electrode layer 180 is disposed on the first well 121P and the third well 123N.

Regarding the operating method of the semiconductor device 100, a gate voltage V_{G} is applied to the electrode layer 180A for generating an inversion layer 121a between the first well 121P and the electrode layer 180. An emitter voltage V_{E} is applied to the first heavily doping region 141N. A collector voltage V_{C} is applied to the second heavily doping region 142N. A base voltage V_{B} is applied to the third heavily doping region 143P. The gate voltage V_{G} is such as between larger than 0 and smaller than 1V. The emitter voltage V_{E} is such as 0V (connected to a grounding end). The collector voltage V_{C} is such as 5˜10V. The base voltage V_{B} is such as 1˜2V. In the present embodiment, the first well 121P, the second well 122N, the first heavily doping region 141N, the second heavily doping region 142N, and the third heavily doping region 143P together can form a NPN type bipolar junction transistor (BJT), and a collector current I_{C} is generated when the semiconductor device 110 is applied with the above-mentioned voltages. The common-emitter current gain (Beta) is represented as collector current I_{C}/base current I_{B}.

When the gate voltage V_{G} is applied to the electrode layer 180, the inversion layer 121a is generated between the first well 121P and the electrode layer 180, rendering the first heavily doping region 141N and the third well 123N electrically connected through the inversion layer 121a. Accordingly, charge carriers flow through the third well 123N, the first well 121P, and the second well 122N via the inversion layer 121a, forming an NPN type parasitic BJT, and another collector current I_{C′} is generated. As such, the original BJT along with the additional parasitic BJT generate two collector currents I_{C} and I_{C′}, and hence, the current gain (Beta) of the semiconductor device 100 is increased from I_{C}/I_{B} to (I_{C}+I_{C′})/I_{B}.

Referring to FIG. 2, a gate voltage-normalization Bate curve of a semiconductor device of an embodiment is shown. As shown in FIG. 2, the gate voltages V_{G} are A, B, C, and D, respectively, wherein A<B<C<D, the values of A˜D are between larger than 0 and smaller than 1V, and the normalization Beta is set to be 1 when the gate voltage V_{G} is 0, where the parasitic BJT is not in operation. By changing the value of the gate voltage V_{G}, as shown in FIG. 2, the normalization Beta can be increased to be larger than 4, and no early effect is observed. In other words, applying a gate voltage V_{G} to the semiconductor device of an embodiment of the present disclosure, the current gain can be increased by more than 4 times, and a normal operation of the device can be maintained. As such, the current gain of the semiconductor device of the present disclosure is increased, thus, the holding voltage can be increased, the occurrence of the latch-up effect can be reduced, and a better electrostatic discharge (ESD) protection is provided.

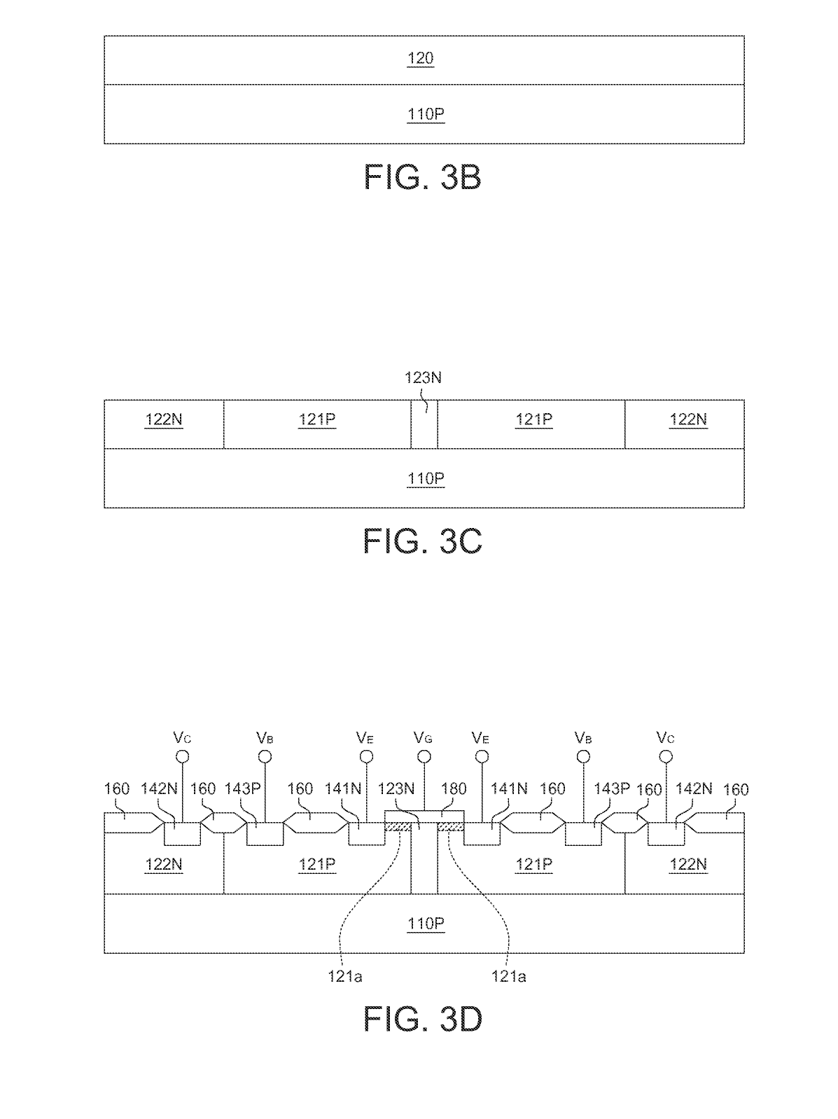

Referring to FIGS. 3A˜3D, a manufacturing method of the semiconductor device 100 of the first embodiment is illustrated. Firstly, as shown in FIG. 3A, the substrate 110P is provided.

Next, as shown in FIG. 3B, an epitaxial layer 120 is formed on the substrate 110P.

Next, as shown in FIG. 3C, the first well 121P and the second well 122N are formed on the substrate 110P. In the embodiment, the third well 123N can further be formed on the substrate 110P, and the first well 121P is located between the second well 122N and the third well 123N. The first well 121P, the second well 122N, and the third well 123N are in the epitaxial layer 120. In the embodiment, the first well 121P, the second well 121N, and the third well 123N are formed by such as a twin well process, and additional masks or processing steps are not required.

Next, as shown in FIG. 3D, the field oxide 160 can be formed on the junction between the first well 121P and the second well 122N. Further, the additional field oxide 160 can be formed between the first heavily doping region 141N and the third heavily doping region 143P, which will be formed in the following process.

Next, as shown in FIG. 3D, the first heavily doping region 141N and the third heavily doping region 143P are formed in the first well 121P, the second heavily doping region 143P is formed in the second well 122N, and the first and the third heavily doping regions 143P and 141N are separated from each other.

Next, as shown in FIG. 3D, the electrode layer 180 is formed on the first well 121P. According to the above-mentioned steps, the semiconductor device 100 of the present embodiment can be manufactured.

### Second Embodiment

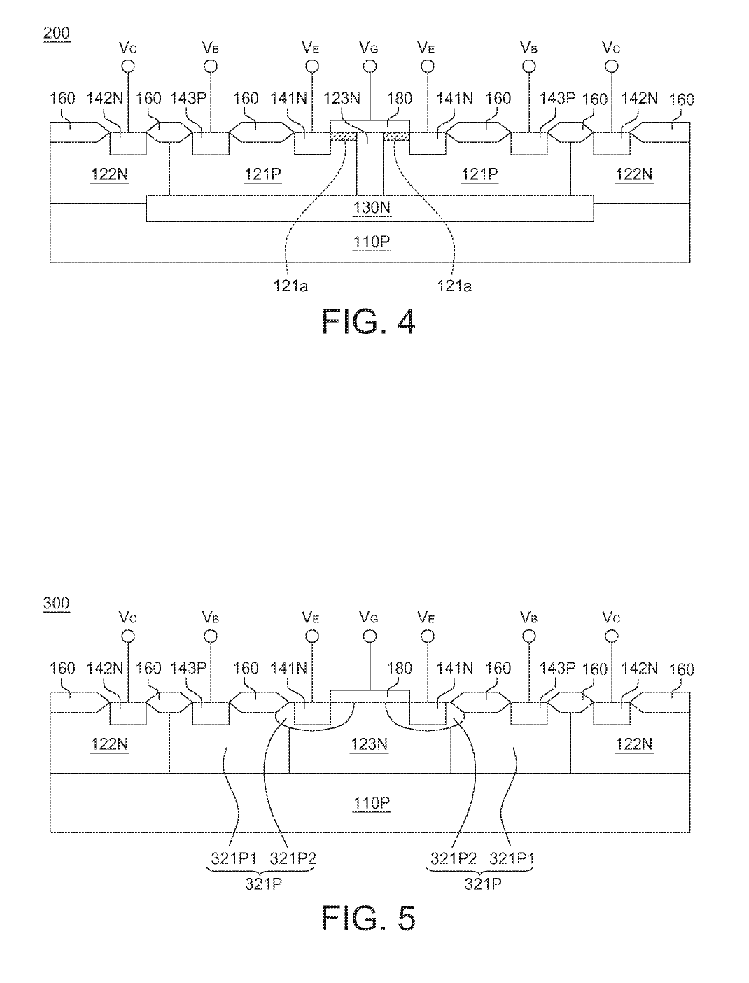

Referring to FIG. 4, a cross section view of a semiconductor device 200 of the second embodiment is shown. The semiconductor device 200 of the present embodiment is different from the semiconductor device 100 of the first embodiment in a buried layer 130N, and the similarities are not repeated here.

As shown in FIG. 4, the buried layer 130N is disposed below the first well 121P and the second well 122N, and the buried layer 130N has the first type doping. The materials of the buried layer 130N, the second well 122N, and the third well 123N of the present embodiment are substantially the same. In the present embodiment, the first type doping is N type doping, the buried layer 130N is such as N type buried layer (NBL), an N type epitaxial layer (N-epi), a deep N type well, or a multiple N+ stacked layer.

The manufacturing method of the semiconductor device 200 of the second embodiment is different from the manufacturing method of the semiconductor device 100 of the first embodiment in that, the buried layer 130N is formed before the formation of the epitaxial layer 120, and the similarities are not repeated here.

The operating methods of the semiconductor devices 100 and 200 are the same. When the gate voltage V_{G} is applied to the electrode layer 180, the inversion layer 121a is generated between the first well 121P and the electrode layer 180, rendering the first heavily doping region 141N and the third well 123N electrically connected through the inversion layer 121a. Accordingly, charge carriers flow through the third well 123N, the buried layer 130N, and the second well 122N via the inversion layer 121a, generating another collector current I_{C′}. As such, the collector currents I_{C} generated by the original BJT is combined with the additional collector current I_{C′}, and hence, the current gain (Beta) of the semiconductor device 200 is increased from I_{C}/I_{B} to (I_{C}+I_{C′})I_{B}.

### Third Embodiment

Referring to FIG. 5, a cross section view of a semiconductor device 300 of the third embodiment is shown. The semiconductor device 300 of the present embodiment is different from the semiconductor device 100 of the first embodiment in the design of the first well 321P, and the similarities are not repeated here.

In the present embodiment, as shown in FIG. 5, the first well 321P includes a first region 321P1 and a second region 321P2. The first heavily doping region 141N is in the first region 321P1, the third heavily doping region 143P is in the second region 321P2, and a partial region of the third well 123N is located between the first region 321P1 and the substrate 110P. In the present embodiment, the second region 321P2 surrounds the first heavily doping region 141N. The first region 321P1 is located adjacent to and electrically connected to the second region 321P2.

The manufacturing method of the semiconductor device 300 of the third embodiment is different from the manufacturing method of the semiconductor device 100 of the first embodiment in that, the first region 321P1 of the first well 321P, the second well 122N, and the third well 123N are formed before the formation of the second region 321P2 of the first well 321P followed by the formation of the heavily doping regions, and the similarities are not repeated here.

The operating methods of the semiconductor devices 100 and 300 are the same, and the similarities are not repeated here.

### Fourth Embodiment

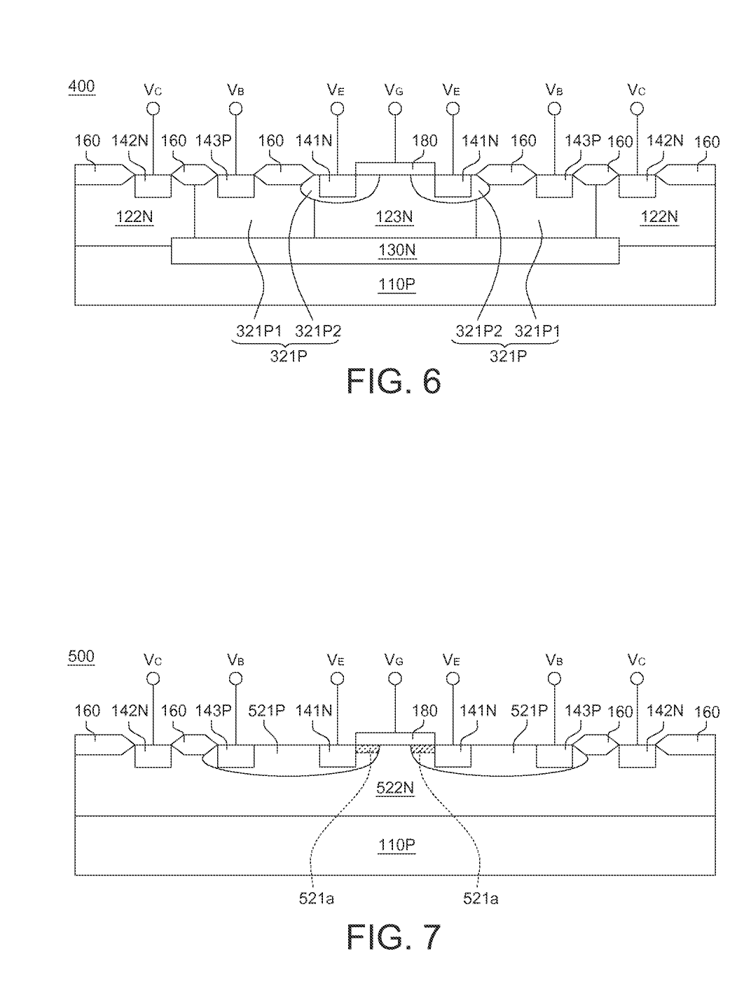

Referring to FIG. 6, a cross section view of a semiconductor device 400 of the fourth embodiment is shown. The semiconductor device 400 of the present embodiment is different from the semiconductor device 300 of the third embodiment in a buried layer 130N, and the similarities are not repeated here.

As shown in FIG. 6, the buried layer 130N is disposed below the first well 121P, the second well 122N, and the third well 123N, and the buried layer 130N has the first type doping. The property of the buried layer 130N is as above-mentioned, and the similarities are not repeated here.

The operating methods of the semiconductor devices 400 and 200 are the same, and the similarities are not repeated here.

### Fifth Embodiment

Referring to FIG. 7, a cross section view of a semiconductor device 500 of the fifth embodiment is shown. The semiconductor device 500 of the present embodiment is different from the semiconductor device 100 of the first embodiment in the design of the first well 521P and the second well 522N, and the similarities are not repeated here.

As shown in FIG. 7, in the semiconductor device 500, the second well 522N surrounds the first well 521P. The electrode layer 180 is disposed on the second well 522N. The first heavily doping region 141N and the third heavily doping region 143P are disposed in the first well 521P, the second heavily doping region 142N is disposed in the second well 522N, and the first and third heavily doping regions are separated from each other.

The operating methods of the semiconductor devices 100 and 500 are the same. When the gate voltage V_{G} is applied to the electrode layer 180, the inversion layer 521 a is generated between the first well 521P and the electrode layer 180, rendering the first heavily doping region 141N and the second well 522N electrically connected through the inversion layer 521a. Accordingly, charge carriers flow through the second well 522N via the inversion layer 521a, generating another collector current I_{C′}. As such, the collector currents I_{C} generated by the original BJT is combined with the additional collector current I_{C′} generated from applying the gate voltage V_{G}, and hence, the current gain (Beta) of the semiconductor device 500 is increased from I_{C}/I_{B} to (I_{C}+I_{C′})I_{B}.

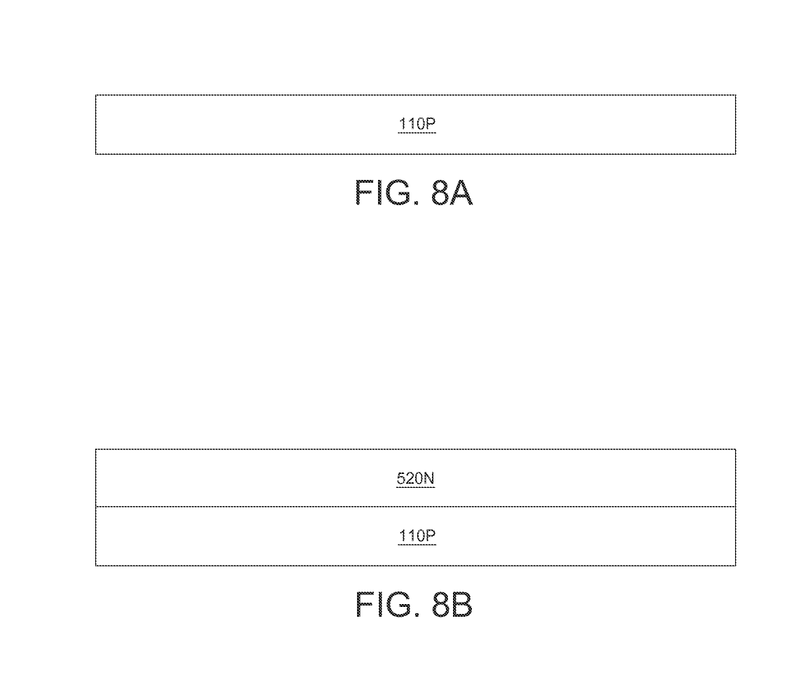

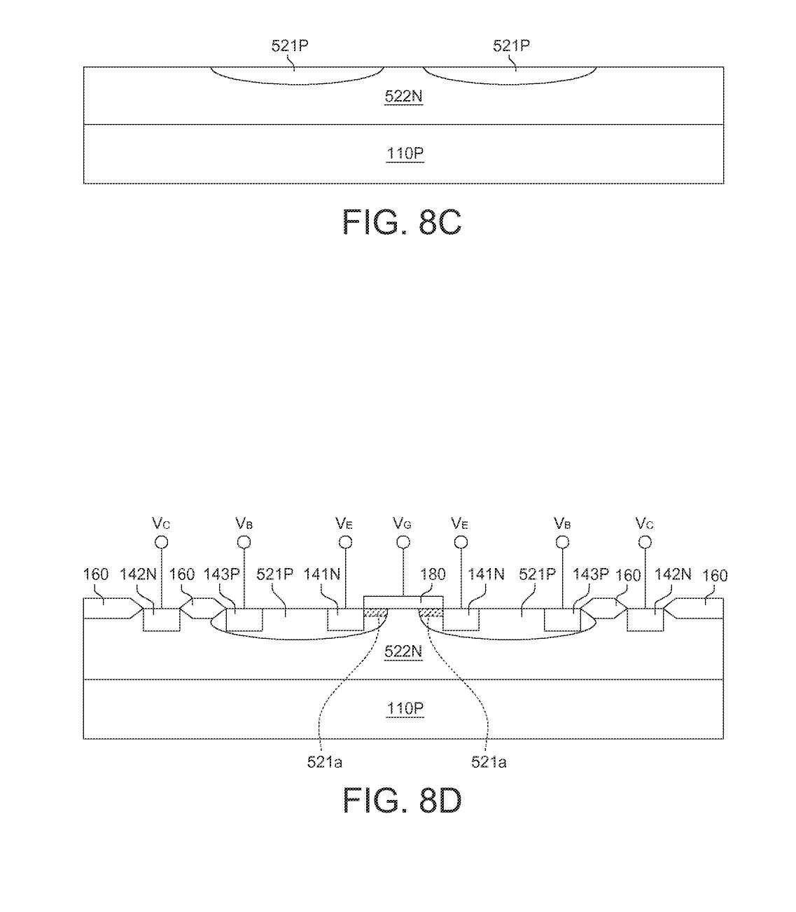

Referring to FIGS. 8A-8D, a manufacturing method of the semiconductor device 500 of the fifth embodiment is illustrated. The manufacturing method of the semiconductor device 500 of the fifth embodiment is different from the manufacturing method of the semiconductor device 100 of the first embodiment in the manufacturing process of the first well 521P and the second well 422N, and the similarities are not repeated here. Firstly, as shown in FIG. 8A, the substrate 110P is provided.

Next, a doped layer 520N is formed on the substrate 110P, and the doped layer 520N has the first type doping.

Next, as shown in FIG. 8C, the first well 521P and the second well 522N are formed. In the present embodiment, the first well 521P and the second well 522N are formed by such as an implantation process or a diffusion process.

Next, as shown in FIG. 8D, the first heavily doping region 141N and the third heavily doping region 143P are formed in the first well 521P, the second heavily doping region 142N is formed in the second well 522N, and the first and third heavily doping regions are separated from each other.

Next, as shown in FIG. 8D, the electrode layer 180 is formed on the first well 52P. According to the above-mentioned steps, the semiconductor device 500 of the present embodiment can be manufactured.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a first well disposed on the substrate;
a second well disposed on the substrate;
a first heavily doping region disposed in the first well;
a second heavily doping region disposed in the second well;
a third heavily doping region disposed in the first well, wherein the first heavily doping region and the third heavily doping region are separated from each other; and
an electrode layer disposed on the first well;
wherein each of the second well, the first heavily doping region, and the second heavily doping region has a first type doping, each of the substrate, the first well, and the third heavily doping region has a second type doping, and the first type doping is complementary to the second type doping.

2. The semiconductor device according to claim 1, further comprising:
a field oxide (FOX) disposed on a junction between the first well and the second well.

3. The semiconductor device according to claim 1, further comprising:
a buried layer disposed below the first well and the second well, wherein the buried layer has the first type doping.

4. The semiconductor device according to claim 1, further comprising:
a third well disposed on the substrate, wherein the first well is disposed between the second well and the third well, and the third well has the first type doping.

5. The semiconductor device according to claim 4, wherein the electrode layer is disposed on the third well.

6. The semiconductor device according to claim 4, wherein the first well comprises a first region and a second region, the first heavily doping region is in the first region, the third heavily doping region is in the second region, and a partial region of the third well is located between the first region and the substrate.

7. The semiconductor device according to claim 6, further comprising:
a buried layer disposed below the first well, the second well, and the third well, wherein the buried layer has the first type doping.

8. The semiconductor device according to claim 1, wherein the second well surrounds the first well.

9. The semiconductor device according to claim 8, wherein the electrode layer is disposed on the second well.

10. A manufacturing method of a semiconductor device, comprising:
providing a substrate;
forming a first well and a second well on the substrate;
forming a first heavily doping region in the first well;
forming a second heavily doping region in the second well;
forming a third heavily doping region in the first well, wherein the first heavily doping region and the third heavily doping region are separated from each other; and
forming an electrode layer on the first well, wherein each of the second well, the first heavily doping region, and the second heavily doping region has a first type doping, each of the substrate, the first well, and the third heavily doping region has a second type doping, and the first type doping is complementary to the second type doping.

11. The manufacturing method of the semiconductor device according to claim 10, further comprising:
forming a filed oxide (FOX) on a junction between the first well and the second well.

12. The manufacturing method of the semiconductor device according to claim 10, further comprising:
forming a buried layer below the first well and the second well, wherein the buried layer has the first type doping.

13. The manufacturing method of the semiconductor device according to claim 10, further comprising:
forming a third well on the substrate, wherein the first well is located between the second well and the third well, and the third well has the first type doping.

14. The manufacturing method of the semiconductor device according to claim 13, wherein the electrode layer is disposed on the third well.

15. The manufacturing method of the semiconductor device according to claim 13, wherein the step of forming the first step comprises:
forming a first region and a second region, wherein the first heavily doping region is in the first region, the third heavily doping region is in the second region, and a partial region of the third well is located between the first region and the substrate.

16. The manufacturing method of the semiconductor device according to claim 15, further comprising:
forming a buried layer below the first well, the second well, and the third well, wherein the buried layer has the first type doping.

17. The manufacturing method of the semiconductor device according to claim 10, wherein the second well surrounds the first well.

18. The manufacturing method of the semiconductor device according to claim 17, wherein the electrode layer is formed on the second well.

19. An operating method of a semiconductor device, wherein the semiconductor device comprises a substrate, a first well, a second well, a first heavily doping region, a second heavily doping region, a third heavily doping region, and an electrode layer; the first well and second well are disposed on the substrate; the first heavily doping region is disposed in the first well; the second heavily doping region is disposed in the second well; the third well is disposed in the first well and is separated from the first well; the electrode layer is disposed on the first well; each of the second well, the first heavily doping region, and the second heavily doping region has a first type doping; each of the substrate, the first well, and the third heavily doping region has a second type doping; the first type doping is complementary to the second type doping; and the operating method comprises:
applying a gate voltage to the electrode layer for generating an inversion layer between the first well and the electrode layer;
applying an emitter voltage to the first heavily doping region;
applying a collector voltage to the second heavily doping region; and
applying a base voltage to the third heavily doping region.

20. The operating method of the semiconductor device according to claim 19, wherein the gate voltage is between larger than 0 and smaller than 1 V.
